(19) United States
(12) Patent Application Publication
(10) Pub. No.: US 2024/0302439 A1
(43) Pub. Date: Sep. 12, 2024

(54) BATTERY STATE OF CHARGE ESTIMATION

(71) Applicant: Powin, LLC, Portland, OR (US)

(72) Inventors: Samuel Gilbert Orion Beck, Portland, OR (US); Robert Blake Hayden Rector, Petaluma, CA (US); Peter Brody-Moore, Denver, CO (US); Susannah Alice Crowell, West Orange, NJ (US)

(73) Assignee: Powin, LLC, Portland, OR (US)

(21) Appl. No.: 18/137,362

(22) Filed: Apr. 20, 2023

Related U.S. Application Data
(60) Provisional application No. 63/451,512, filed on Mar. 10, 2023.

(51) Int. Cl. G01R 31/367; G01R 31/374; G01R 31/3842; G01R 31/396; G06N 3/09

(52) U.S. Cl. CPC G01R 31/367; G01R 31/374; G01R 31/3842; G01R 31/396; G06N 3/09

(57) ABSTRACT

The present disclosure provides techniques and solutions for obtaining state of charge estimates for one or more battery cells. A set of values is obtained for a set of one or more battery cells. The set of values includes a least one voltage measurement, at least one present current measurement, and at least one temperature measurement. The set of input values is submitted to a state of charge estimation model, as well as at least one prior current value for the set of one or more battery cells. A state of charge estimate is received for the set of one or more battery cells. In various implementations, the state of charge estimation model can be implemented as a machine learning model or as a lookup table. An estimate from the charge estimation model may be combined with one or more other state of charge estimates.

### CROSS REFERENCE TO RELATED APPLICATION

This application claims the benefit of U.S. Provisional Patent Application No. 63/451,512, filed on Mar. 10, 2023, incorporated herein by reference in its entirety.

### FIELD

The present disclosure relates to providing state of charge estimates for a battery cell or a collection of battery cells.

### BACKGROUND

Batteries are used in a wide variety of applications, some critical and some less so. In some cases, the amount of charge left in a battery is not of significant concern. For example, typical household batteries (the familiar “AA,” “AAA,” “C,” “D,” and 9-volt batteries) are often used until the batteries charge is depleted, at which point the old batteries are discarded and replaced with new ones. In a few cases, devices that use such batteries may have rudimentary indicators of remaining battery life, or provide a warning when remaining battery charge is below a threshold level (recall the “chirp” of battery powered smoke detectors).

While many types of household batteries are not intended to be recharged (or if they do, the batteries are often simply recharged after a prior charge is depleted), a variety of other types of batteries are intended to be recharged, including batteries used in consumer applications (electronics, automobiles) and batteries used in more industrial/enterprise applications, such as batteries in medical equipment or for off-grid storage, such as battery backup systems that may be charged by various renewable energy sources, or are used to regulate power delivered to the grid from renewable energy sources (or optionally non-renewable sources).

Whether for consumer or non-consumer applications, rechargeable batteries are used in many situations where some estimate of remaining battery life/charge is desirable. Consumers are quite interested in how much battery life remains in their smartphone, tablets, or laptops. However, the importance of having accurate battery charge estimates can vary widely among applications. A fairly inaccurate result may be “good enough” for consumer electronic devices, while more accurate estimates may be desired for electric vehicles, medical applications or off-grid storage/renewable energy power management applications.

A variety of techniques are available to measure battery charge, but suffer from various drawbacks/sources of inaccuracy. In particular, inaccuracies can be introduced into some charge measurement methods, including voltage-based measurements and “coulomb counting” techniques, including due to factors such as ambient temperature, discharge rate, battery age, cell material, and sensor accuracy can affect measured current or voltage. Voltage curves for batteries are often non-linear, which can result poor accuracy when a battery is not close to being fully charged or fully discharged.

Certain measurement methods, including some voltage measurement techniques, require a battery to be in a relaxed state for a period of time to maximize accuracy, including to account for hysteresis effects. Problems with coulomb counting methods include that it may be necessary to perform an initial calibration for a battery to obtain accurate results, and that sensor measurement errors can accumulate over time to cause more serious inaccuracies in state of charge estimates. Additional issues with coulomb counting methods include various leakage currents involved with battery operations, and that battery capacity tends to degrade over time. Accordingly, room for improvement exists.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

The present disclosure provides techniques and solutions for obtaining state of charge estimates for one or more battery cells. A set of values is obtained for a set of one or more battery cells. The set of values includes a least one voltage measurement, at least one present current measurement, and at least one temperature measurement. The set of input values is submitted to a state of charge estimation model, as well as at least one prior current value for the set of one or more battery cells. A state of charge estimate is received for the set of one or more battery cells. In various implementations, the state of charge estimation model can be implemented as a machine learning model or as a lookup table. An estimate from the charge estimation model may be combined with one or more other state of charge estimates.

In one aspect, the present disclosure provides a process for obtaining a state of charge estimate for one or more battery cells. A first set of values is received from one or more sets of hardware sensors associated with a first set of one or more battery cells, the first set of values comprising at least voltage measurement value, at least one present current measurement value, and at least one temperature measurement value. A first set of input values is submitted to a first state of charge estimation model, the first set of input values from the first set of values and at least one prior current value for the first set of one or more battery cells. A first state of charge estimate is received for the first set of input values from the first state of charge estimation model.

The present disclosure also includes computing systems and tangible, non-transitory computer readable storage media configured to carry out, or including instructions for carrying out, an above-described method. As described herein, a variety of other features and advantages can be incorporated into the technologies as desired.

### BRIEF DESCRIPTION OF THE DRAWINGS

FIG. 1 is a block diagram of an example energy storage unit, and computing system that calculates state of charge estimates, with which disclosed techniques can be implemented.

FIG. 2 is a flowchart of a process for obtaining a state of charge estimate according to a disclosed technique.

FIG. 3 is a flowchart of a process for obtaining a state of charge estimate produced according to a disclosed technique and a state of charge estimate according to another state of charge estimation technique.

FIG. 4 is a flowchart of obtaining a state of charge estimate using different model types created using a disclosed technique.

FIG. 5 is a flowchart of a process for creating a state of charge estimation model according to a disclosed technique.

FIGS. 6A-6E provide example python code useable to implement aspects of the present disclosure related to obtaining data for use in creating a state of charge estimation model.

FIG. 7 provides example python code useable to generate a lookup table using data obtained using a process that employs the code of FIGS. 6A-6E.

FIGS. 8A and 8B provide an example state of charge estimate lookup table prepared according to a disclosed technique, and illustrates how the table can be used to provide a state of charge estimate for a particular set of input values.

FIG. 9 is a flowchart of example operations in a disclosed process of obtaining state of charge estimates for one or more battery cells.

FIG. 10 is a diagram of an example computing system in which some described embodiments can be implemented.

FIG. 11 is an example cloud computing environment that can be used in conjunction with the technologies described herein.

### DETAILED DESCRIPTION

### Example 1—Overview

Batteries are used in a wide variety of applications, some critical and some less so. In some cases, the amount of charge left in a battery is not of significant concern. For example, typical household batteries (the familiar “AA,” “AAA,” “C,” “D,” and 9-volt batteries) are often used until the batteries charge is depleted, at which point the old batteries are discarded and replaced with new ones. In a few cases, devices that use such batteries may have rudimentary indicators of remaining battery life, or provide a warning when remaining battery charge is below a threshold level (recall the “chirp” of battery powered smoke detectors).

While many types of household batteries are not intended to be recharged (or if they do, the batteries are often simply recharged after a prior charge is depleted), a variety of other types of batteries are intended to be recharged, including batteries used in consumer applications (electronics, automobiles) and batteries used in more industrial/enterprise applications, such as batteries in medical equipment or for off-grid storage, such as battery backup systems that may be charged by various renewable energy sources, or are used to regulate energy delivered to the grid from renewable energy sources (or optionally non-renewable sources).

Whether for consumer or non-consumer applications, rechargeable batteries are used in many situations where some estimate of remaining battery life/charge is desirable. Consumers are quite interested in how much battery life remains in their smartphone, tablets, or laptops. However, the importance of having accurate battery charge estimates can vary widely among applications. A fairly inaccurate result may be “good enough” for consumer electronic devices, while more accurate estimates may be desired for electric vehicles, medical applications or off-grid storage/renewable energy power management applications.

A variety of techniques are available to measure battery charge, but suffer from various drawbacks/sources of inaccuracy. In particular, inaccuracies can be introduced into some charge measurement methods, including voltage-based measurements and “coulomb counting” techniques, including due to factors such as ambient temperature, discharge rate, battery age, cell material, and sensor accuracy can affect measured current or voltage. Voltage curves for batteries are often non-linear, which can result poor accuracy when a battery is not close to being fully charged or fully discharged.

Certain measurement methods, including some voltage measurement techniques, require a battery to be in a relaxed state for a period of time to maximize accuracy, including to account for hysteresis effects. Problems with coulomb counting methods include that it may be necessary to perform an initial calibration for a battery to obtain accurate results, and that sensor measurement errors can accumulate over time to cause more serious inaccuracies in state of charge estimates. Additional issues with coulomb counting methods include various leakage currents involved with battery operations, and that battery capacity tends to degrade over time. Accordingly, room for improvement exists.

In one aspect, the present disclosure provides a point (or “instantaneous”) state of charge estimate a particular battery cell, or a collection of battery cells. An estimation process takes as input a presently measured voltage of the battery cell, the present measured current of the battery cell, a recently measured current of the battery cell, and the present measured temperature of the battery cell. The estimate is provided based on comparing a particular set of input values with a model created using historical data. In various implementations, the historical data can be used to construct a lookup table or can be used to train a machine learning model that provides an estimated state of charge in response to a set of input values.

In another aspect, the present disclosure provides techniques for identifying historical data values to be used in model training. For example, it can be useful to identify historical data with values at various locations on a spectrum of values that are likely to be encountered for a particular battery system for the input values-cell voltage, present current, recent current, and temperature, including combinations of these values (e.g., comparatively high cell voltage with comparatively low temperature, comparatively high voltage with comparatively lower temperature). Selecting appropriate values can help ensure that the model can provide accurate results under a variety of conditions, including having entries in a lookup table for such values or having a machine learning model trained with such values, so that inference results are likely to have improved accuracy as compared with a model trained without similar training data.

A disclosed state of charge point estimate technique can optionally be combined with other state of charge estimation methods, including through the use of various filters. In a particular example, a battery state of charge estimate is obtained using a coulomb counting method, and the result is combined with a value obtained by a disclosed point estimate technique using a Kalman filter to provide a combined state of charge estimate.

The techniques described above can be advantageously used in a variety of applications. For example, more accurate charge estimation methods may be particularly valuable in transportation applications, such as an estimate of available battery power for an electric vehicle, which can be converted into an estimate of available driving range. Given the current development state of EV charging networks in many jurisdictions, having accurate estimates of driving range can be of particular value.

The techniques can be particularly useful in off-grid energy storage, such as battery installations used to store energy generated by various renewable energy sources. Battery installations typically have multiple battery racks, where each battery rack contains multiple cells. The battery cells of the battery racks can be connected in different ways-different combinations of parallelly and serially connected battery cells, which can in some cases complicate attempts to determine available battery cell charge (either on a cell-by-cell basis, or for collections of cells, such as racks, or groups of racks). The improved charge estimates provided by disclosed techniques can help address these issues.

Having more accurate estimates of battery state of charge can help in ways in addition to providing more accurate estimates of available charge (such as in terms of available amp hours our watt hours). For example, by having accurate assessments of charge in various battery cells or collections of cells, an operator (or computer-implemented process) that manages a battery installation can more accurately determine from which battery cells/collections to provide energy, and to which battery cells/collections energy should be provided, such as to increase their state of charge. In general, having more accurate state of charge estimates can help with charge balancing within a battery installation and managing charge supply/demand issues.

### Example 2—Example Energy Storage Unit in Communication with Computing System Providing State of Charge Estimation Model

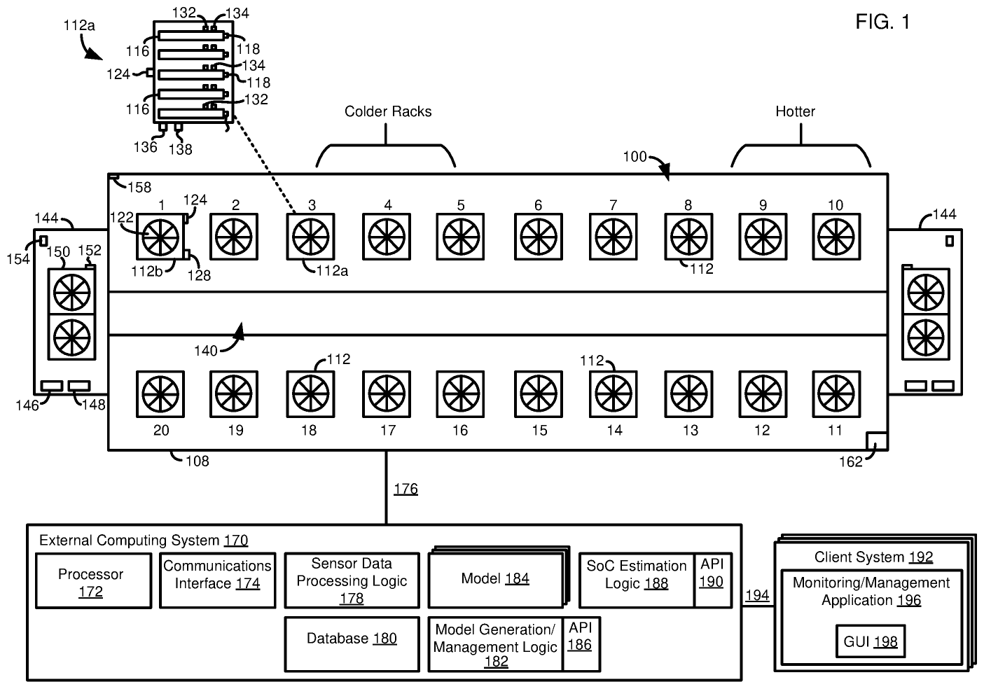

FIG. 1 illustrates an example apparatus with which disclosed techniques can be implemented. The apparatus is in the form of an energy storage unit 100 that includes an enclosure 108 that houses a plurality of battery racks 112. Without limiting the scope of the present disclosure, battery racks that are suitable for use as the battery racks 112 include STACK™ battery racks, available from Powin LLC, of Portland, Oregon.

As shown for a battery rack 112a, which can be representative of the other battery racks 112, a given battery rack includes a plurality of battery cells 116 distributed throughout the rack. Because some of the cells are closer to the exterior of the battery rack 112a, and some are closer to the center, the temperatures of cells within the battery rack can vary. In at least some implementations, one or more of the battery cells 116 can include a temperature sensor 118. A battery cell 116 can include multiple temperature sensors 118, such as having temperature sensors located at terminals between cells. Temperature variations can affect state of charge calculations for battery cells. Disclosed techniques can provide an estimate of the state of battery charge using input that incudes a battery cell temperature, which can be provided by a respective temperature sensor 118 of a respective battery cell 116.

A given battery rack 112 can include other components, as shown for battery rack 112b, which can also be representative of the other battery racks. In particular, the battery rack 112b is shown as including a fan 122. Although a single fan 122 is shown, in practice a given battery rack 112 can include multiple fans. When multiple fans 122 are included, the fans for a given battery rack 112 can be controlled as a unit (in other words, all fans can be turned on or off according to a control signal) or individual rack fans or subsets of rack fans can be controlled separately.

In some cases, battery rack fans 122 can be integral to the battery rack, while in other cases the battery rack fans can be separate from, but typically proximate to, a battery rack to be temperature regulated by a respective battery rack fan. For example, the battery racks 112 and the battery rack fans 122 can be mounted separately within the enclosure 108, including where the battery rack fans are included in the enclosure during manufacture, and where the battery racks can be installed later/as separate components. Although a single battery rack 112 is shown with a single battery rack fan 122 (which can represent a set of fans), in other cases a single battery rack fan can be responsible for ventilating multiple battery racks 112.

The battery rack 112b is shown as including a sensor 124, which can be a temperature sensor. The temperature sensor 124 can be included along with, or in place of, the temperature sensors 118 shown for the battery rack 112a. Although a single temperature sensor 124 is shown, the battery rack 112b can include multiple temperature sensors if desired. In other cases, a battery rack 112 can omit a temperature sensor 124.

The temperature sensors 118, 124 can provide information, such as temperature readings, to a processor 128 of the battery rack 112b. The processor 128 can in turn send temperature information to other components of the energy storage unit 100, or to components outside of the energy storage unit 100 that can be used to manage operation of the energy storage unit, including a remote workstation that can be used to monitor and manage multiple energy storage units. Managing operation of the energy storage unit 100 can include operations that are based on battery state of charge estimates produced using disclosed techniques.

In turn, the processor 128 can receive commands from other components of the energy storage unit 100 or from outside of the energy storage unit. In particular, the processor 128 can receive commands to adjust an operational state of the battery rack fans 122, such as commands to turn a fan on or turn a fan off. Commands can also include commands to add, reduce, or remove current applied to/drawn from a battery cell 116 or a collection of battery cells.

A battery rack 112, or individual battery cells 116 of a battery rack, can include additional sensors, which can also be in communication with the processor 128. As shown, the battery cells 116 of the battery rack 112a include current sensors 132 and voltage sensors 134. Similarly, the battery rack 112a can include a current sensor 136 or a voltage sensor 138. Although shown as separate, two more types of sensors can be combined in a single operational unit.

The current sensors 132, 136 and the voltage sensors 134, 138 can be used to provide current and historical current readings, as well as current voltage readings, for use in a disclosed battery state of charge estimation technique. Typically, it is desirable to use readings from the sensors 132, 136 for calculations, to account for differences between cells 116 in a battery rack 112. However, in the event that individual battery cell sensors 132, 136 are not available, or are not operating as desired, information from the sensors 136, 138 can be used to provide current or voltage measurements for battery cells 116 in the stack. In the event current or voltage measurements are obtained from the sensors 136, 138, the measurements can optionally be adjusted using temperature data for individual cell temperature sensors 118 or the temperature sensor 124 for associated battery racks 112.

It is typically desirable to provide ventilation to help regulate the temperature of the battery racks 112. The energy storage unit 100 can be used in a variety of operational scenarios, including in situations where the energy storage unit 100 experiences variable ambient temperatures, such as when an energy storage unit is placed in an outdoor location and can experience different temperatures depending on a time of day or season. It may be desirable to heat the battery racks 112 if they become too cold, or to cool the battery racks if they become too hot. Temperatures within the enclosure 108 can also vary depending on the operational status of the battery racks 112, such as if the temperature increases as cells within the battery racks are charged or discharged.

Because of the arrangement of the battery racks 112 within the enclosure 108, some battery racks may be hotter or cooler than other battery racks, either based on their operational status or the operational status of battery racks proximate a given battery rack, or based on their location within the enclosure. As discussed above, temperature differences between battery stacks 112, and their component battery cells 116, can affect state of charge estimates. The temperature sensors 118, 124 can be used to help provide improved state of charge estimates, as well as being used to help regulate/balance temperatures within the enclosure 108.

Typically, the enclosure 108 and the arrangement of the battery racks 112 within the enclosure are configured to provide fluid passageways (e.g., for air) that can be used to help ventilate the battery racks in order to help regulate their temperatures. The enclosure 108 is shown as including a central duct 140 about which the battery racks 112 are arranged. The central duct 140 extends through the enclosure 108 from opposing ends of the enclosure.

The central duct 140 is shown as in communication with HVAC units 144. Although two HVAC units 144 are shown, in practice a single HVAC unit can be used, or more than two HVAC units can be present. Similarly, although a single fluid passageway (the duct 140) is shown, the enclosure 108 can include multiple fluid passageways, the location and configuration of which can vary. Although shown and described as HVAC units 144, in practice a component can be used that provides less than all functionality of an HVAC unit, such as performing one or more of heating, ventilation, and air conditioning. In yet a further embodiment, the energy storage unit 100 can omit HVAC units 144, and temperature can be regulated by the battery rack fans 122.

As shown, an HVAC unit 144 includes a heating component 146, a cooling component, 148, and ventilation component 150 (such as a fan). An HVAC unit 144 can also include a temperature sensor 152, which can be used to measure a temperature of the enclosure 108, or of air passing through the central duct 140 (which also can be used to regulate the temperature of the enclosure). Optionally, the enclosure 108 can include one or more temperature sensors 158 at one or more locations within the enclosure (or optionally on the exterior of the enclosure).

An HVAC unit 144 is also shown as including a processor 154. The processor 154 can optionally be in communication with the processors 128 of the battery racks 112 (and in turn receive data from the sensors 116, 118, 124, 132, 134, 136, 138). As described for the processors 128, the processor 154 can be in communication with a processor external to the enclosure 108, such as at a remote workstation. In a further embodiment, the processors 128 or the processor 154 can be in communication with a processor 162 of the energy storage unit 100. The processor 162, or another processor associated with or in communication with the energy storage unit 100, can be used to implement disclosed charge estimation techniques, or such actions be performed by the processor external to the enclosure 108.

FIG. 1 illustrates an example external computing system 170, which can include an external processor 172 (corresponding to an implementation of the previously described external processor). The external computing system 170 can include a communication interface 174, which can be used to receive data from, and optionally send data to, the energy storage unit 100, or particular components thereof. The external computing system 170 can communicate with the energy storage unit 100 over a communication connection 176, such as a communication connection 1070 as described in Example 7, or a network environment as discussed in Example 9.

Data received from the energy storage unit 100 over the communication connection 176 can be processed using sensor data processing logic 178. Among other things, the sensor data processing logic 176 can format/extract data received from the energy storage unit, and can store the data, such as in a database 180. In turn, the data, obtained either directly from the sensor data processing logic 176 or from the database 180, can be accessed by model generation/management logic 182. The model generation/management logic 180 can be used to generate models 184 that can be used to obtain state of charge estimates, including using the techniques described in Examples 3-5. The model generation/management logic 182 can include an API 186 (application programming interface), which can be used to create, edit, or delete models, update model generation techniques or parameters, set particular models to be used with particular data sources (such as a client system 192 or component thereof), among other operations.

The models 184 can be accessed by state of charge estimation logic 188. The state of charge estimation logic 188 can be configured, for example, to supply input values to a model 184 of the models, and to process input, such as to return a state of charge estimate in response to a state of charge estimation request. The state of charge estimation logic 188 can perform other operations, such as combining information from multiple models 184, including as described in Example 4.

The state of charge estimation logic 188 can be associated with an API 190, where the API is configured to receive and respond to state of charge estimation requests, where a state of charge estimation request, in at least some cases, can specify particular energy storage units 100, or elements thereof, for which an estimate is desired, and optionally a particular model 184 can be used. In some cases, particular request sources (such as a client system 192) can be associated with profiles associating a source with a particular model/energy storage unit (or component thereof). The profiles can be stored in the database 180, or in another type of storage.

The API 186 or the API 190 ca be called by one or more client computing systems 192, such as over a communication connection 194. The communication connection 196 can be as described for the communication connection 176, but the specific type of communication connection used can be the same as, or different from, the type used for the communication connection 176.

A client computing system 192 can include a battery monitoring or management application 196, which can perform operations such as selecting battery operational units (cells, racks, etc.) to be used with particular energy consumers, determining when/how battery cells should be recharged, creating or updating models 184 or configuration information for such models, or for monitoring a state of charge for battery operational units (such as an energy storage unit 100 or component thereof). Information about state of charge estimates, along with other information (such as status information for energy storage units 100, or components thereof, and optionally functionality for controlling the operation of such energy storage units), can be displayed in a user interface, such as a graphical user interface 198.

### Example 3—Example Process for Obtaining State of Charge Estimate

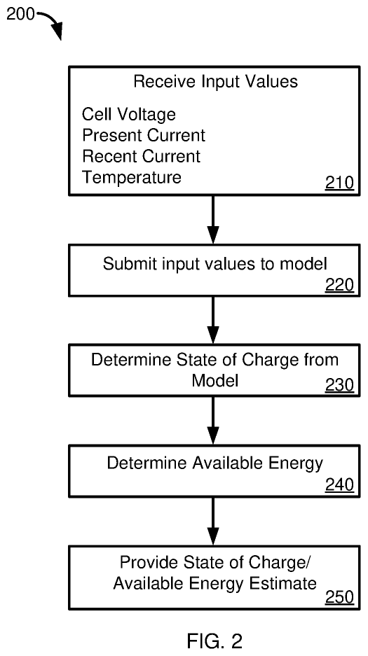

FIG. 2 is a flowchart of a process 200 for determining a battery state of charge using a model (such as a machine learning model or lookup table) creating according to techniques of the present disclosure.

At 210 input values are received for battery-related measurements for a battery, such as a battery cell of a battery rack, for which a state of charge estimate is desired. The input values include a presently measured cell voltage, a presently measured current, a recently measured current value (for example, when the estimates are calculated according to a schedule, or measurements are recorded according to a schedule), and a measured temperature. The input values are submitted to a model at 220. At 230, the state of charge is determined from the model, such as an available amount of amp-hours. Optionally, at 240, the state of charge is converted from amp-hours to a measure of available energy, such as a value in watt-hours. One or both of the state of charge or available energy are provided at 250. Providing the state or charge or available energy estimate can include rendering the values on a user interface, or providing the values to a computing process. For example, it may be desirable to combine values for all battery cells in a battery rack, or to combine values for all battery cells/racks in an energy storage unit or component thereof.

### Example 4—Example Process for Obtaining State of Charge Estimate Based on Multiple State of Charge Estimation Techniques

In some cases, for reasons that will be further described as the specification proceeds, it can be beneficial to combine the results of a model according to disclosed techniques with results from another model. For example, considering a state of charge technique of the present disclosure as an “instantaneous estimate,” it may be beneficial to combine the instantaneous estimate with a value produced using a coulomb counting technique, which techniques are known in the art (for example, as described at batterydesign.net/soc-estimation-by-coulomb counting/).

The results from two or more state of charge estimation techniques (or values derived from such estimates, such as an estimate of available power or energy) can be combined using a suitable algorithm, including a filtering algorithm. The algorithm can be thought of as combining the estimates, or can be thought of as applying a correction factor based on one or more measurement techniques to an estimate based on one or more other techniques. For example, it can be considered that the instantaneous estimate of the present disclosure is used as a correction factor to a state of charge estimate provided by a coulomb counting method, or that the coulomb counting method is used as a correction factor to values obtained using the disclosed instantaneous estimate technique.

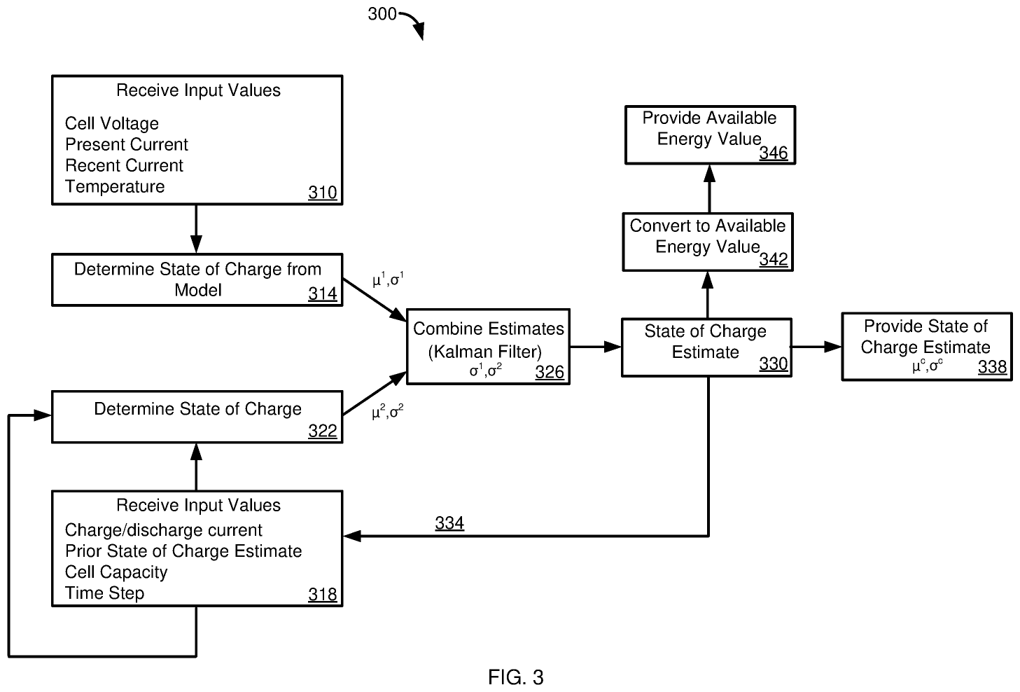

An example process 300 for combining estimates from multiple state of charge techniques is shown in FIG. 3. Input values (such as cell voltage, a presently measured current, a recently measured current, and a temperature) are received at 310, and a state of charge is determined at 314 from the input values using a disclosed state of charge estimation technique. Operations 310 and 314 can correspond to the process 200 of FIG. 2, optionally including converting a state of charge estimate to an estimate of available power or energy.

For another state of charge estimation technique, such as a coulomb counting technique, input values are received at 318. The input values can include a presently measured (such as a charge/discharge current), a prior state of charge estimate, a time between the prior estimate and the current estimate, and a measure of the capacity of the battery cell. A state of charge estimate is determined at 322 from the input values received at 318. Note that input values received at 310 and the input values received at 318 are typically received for the same source-such the same battery cell or set of battery cells. In addition, the input values are typically measured at the same time, or within a determined time range or window (such as where the measurements can occur within ten milliseconds of one another).

In a particular example, the state of charge estimate is calculated at 322 as:

$$SoC ( t ) = SoC ( t - 1 ) + \frac{l ( t )}{{Q}_{n}} Δ t$$

where SoC(t) is the state of charge estimate being calculated, SoC(t−1) is the prior state of charge estimate, I(t) is the measured charging or discharging current at time t, Qn is the battery cell capacity, and Δt is the time step between t−1 and t.

The estimates calculated at 314 and 322 are combined at 326. Along with the estimates (u), uncertainty values (0) can also be provided with a respected value, and these uncertainty values can also be provided with the estimates for combination at 326. In a particular example, the estimates are combined at 326 using a Kalman filter based at least in part on their associated uncertainty values. That is, values from a particular estimation technique having a lower uncertainty value for a particular estimate will be weighted more heavily in the combination than values from an estimation technique having a higher uncertainty value for a corresponding estimate.

The combination at 326 results in an aggregated state of charge estimate at 330, along with an overall uncertainty value. As the inputs used at 318 include a prior state of charge estimate and uncertainty, the aggregate state of charge estimate and overall uncertain can be provided as part of the inputs in an operation 334. In another implementation, the prior estimate using the coulomb counting technique used an input at 318 is based on the state of charge estimate and associated error provided as part of a prior state of charge calculated at 322.

The state of charge estimate, and optionally associated uncertainty, can be provided at 338. Providing the estimate/uncertainty at 338 can include displaying the estimate/uncertainty or providing such values to a computing process.

Optionally, the state of charge estimate can be converted to an available power or energy estimate at 342, where the uncertainty can optionally also be converted to an error in available power or energy. The available power or energy estimate (or uncertainty) can be provided, such as for display or to a computing process, at 346.

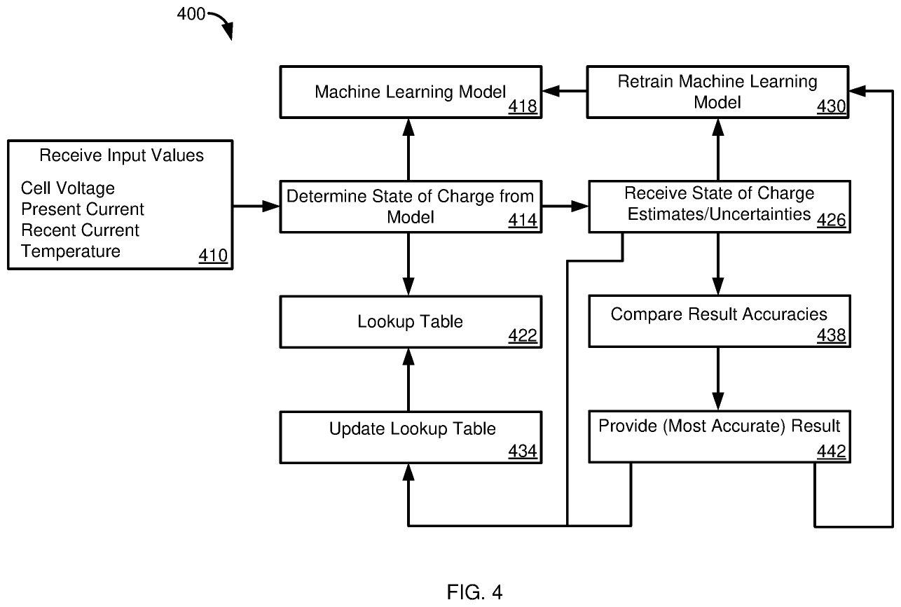

Various modifications can be made to the process 300. For example, the process 200 and the process 300 are described as producing a state of charge estimate using a single model according to the present disclosure, such as either a lookup table or machine learning model. However, in other implementations, multiple state of charge estimation methods of the present disclosure can be used, such as shown in the process 400 of FIG. 4.

In the process 400, input values are received at 410, which can be as described for the analogous operations of the processes 200, 300. State of charge estimates, and uncertainties are determined at 414 using both a machine learning model 418 and a lookup table 422 according to the present disclosure. The results are received at 426.

The machine learning model 418 can be retrained at 430 using the state of charge estimate received at 426. That is, predictions provided by the machine learning model 418 can be added to a set of training data. In some cases, a set, or batch, of machine learning model predictions are stored, and then used together to retrain the machine learning model 418.

In a similar manner, the lookup table 422 can be periodically updated at 434. Particularly as battery properties change over time, including due to hysteresis effects, it can be useful to update the lookup table 422 using more recent data. In some cases, retraining is performed once a suitable number of data observations have been obtained, such as those from the battery cells/racks for which the model is created/used, including those having sufficiently low error values.

At 438, the result accuracies for the machine learning model 418 and the lookup table 422 are compared. A result, such as a most accurate result, is provided at 442. Optionally, retraining of a machine learning model at 430 or update of a lookup table 422, or at least the use of the observation for such purpose, is only performed if the result is the most accurate result, or if the result satisfies a threshold accuracy level. In some cases, an estimation method can transition from using a lookup table 422 to a machine learning model 418 once a threshold accuracy is achieved using the machine learning model, and the comparing operation 438 or the provision of the most accurate result at 442 can be omitted. An estimation process can optionally switch back to the lookup table 422 if a periodic check of the accuracy of the machine learning model 418 does not satisfy a threshold level of accuracy. In a similar manner, accuracy measurements can be used to determine whether an estimate should be provided using a disclosed technique, at least in part, or whether an estimate from another technique, such as coulomb counting, should be used.

### Example 5—Example Process for Obtaining Data for Use in Creating State of Charge Estimation Model

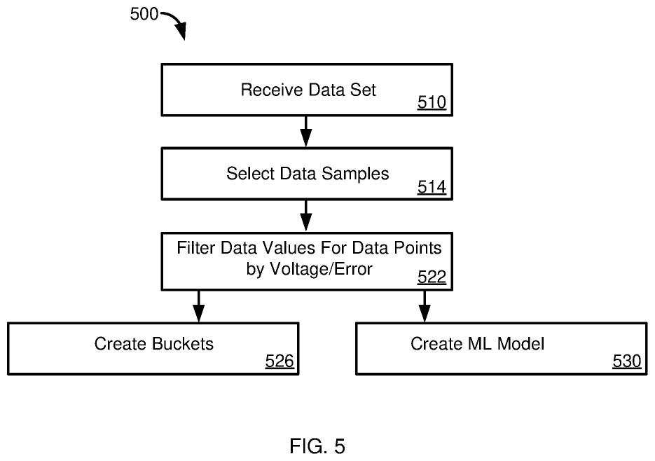

FIG. 5 provides additional details of how a data set can be obtained for use in disclosed state of charge estimation models, either for the creation of a lookup table or use in training a machine learning model.

In a data acquisition process 500, a data set is received at 510. The data set includes current, voltage, and temperature measurements associated with a plurality of battery cells, where the plurality of battery cells can be associated with various racks/enclosures. In some cases, the data set received at 510 can include information associating data with a location source, such as a battery cell/rack/enclosure.

In some cases, all of data received at 510 can be included in subsequent processing. In other cases, such as when a large amount of data is available, data samples are optionally selected at 514. Selecting data samples can be based on a random sampling technique, the application of specified criteria, or using a combination of random sampling and specified criteria. For example, it may be desirable to select sample sets of particular sizes for particular time intervals, for particular battery cells/racks/enclosures, based on operational criteria, such as battery cell temperature, or voltage. From an overall data set, or from subsets created therefrom, random samples can be selected, such as based on a timestamp associated with sets of data points (e.g., a particular set of sensor readings) or based on a position of the set (for example, if the sets are represented in an array or other datatype or data structure) within a group of sets.

Data from the data samples at 514, or from the entire set of data received at 510, are filtered at 522. In particular, it may be useful to select data sets that satisfy particular voltage criteria or are associated with particular error criteria. For example, it may be desirable to determine that data satisfies a high voltage cutoff or a low voltage cutoff value, where values are not used if these criteria are not satisfied. In a particular example, 3000 mV can be set as a cutoff for a low voltage and 3500 mV can be set as a high voltage cutoff (in other words, data will be analyzed if it is between 3000-3500 mV), although these values can be varied as desired, and the cutoff values may be combined with other data selection criteria.

The error criteria can include a maximum error (which can be a particular measure of error, such as a percent error). The maximum error criteria can help improve the quality of a training dataset, and thus a resulting model. That is, selecting a relatively lower amount of error that will be tolerated (which can include having no associated error) can help provide that voltages used in the training data set are accurate, and thus predictions made using a model will also satisfy a desired accuracy level. Otherwise, error in the dataset can be propagated into the model, which will thus have lower accuracy than if model data was limited to datasets known to have satisfactory error.

After filtering at 522, filtered values can be used to create buckets to be used for a lookup table at 526, a machine learning model can be created (trained) at 530, or both types of models can be created.

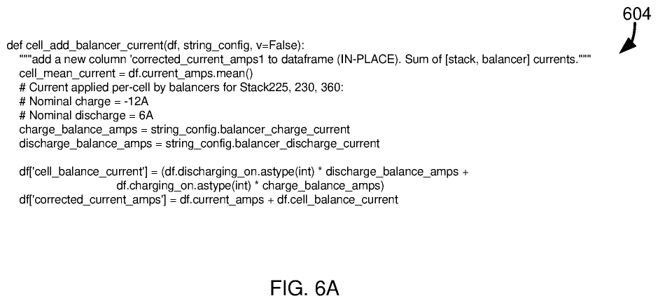

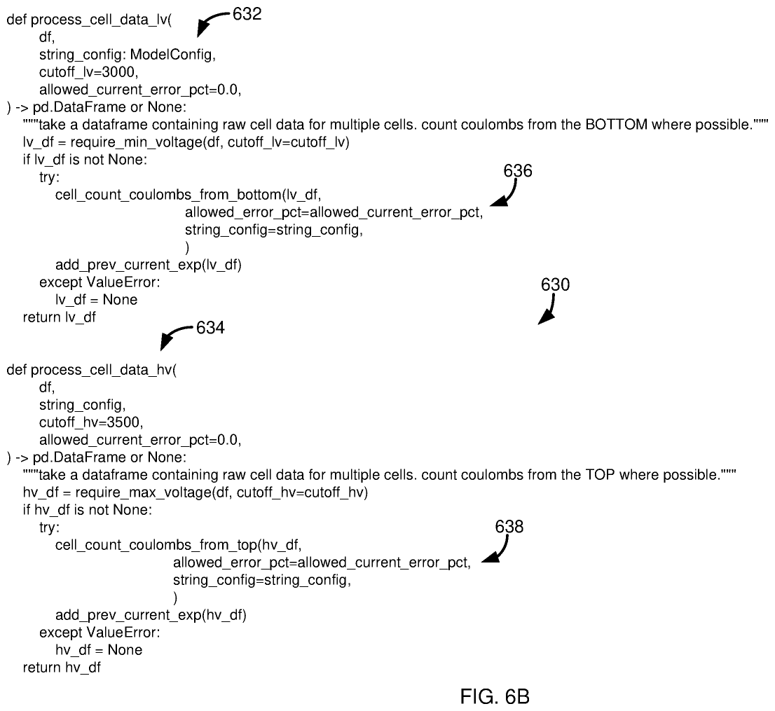

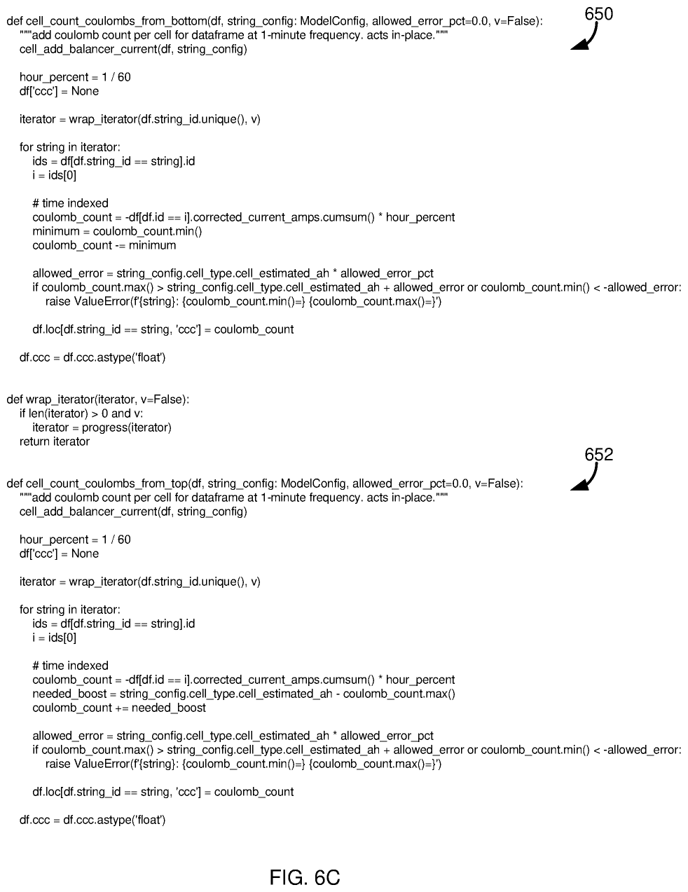

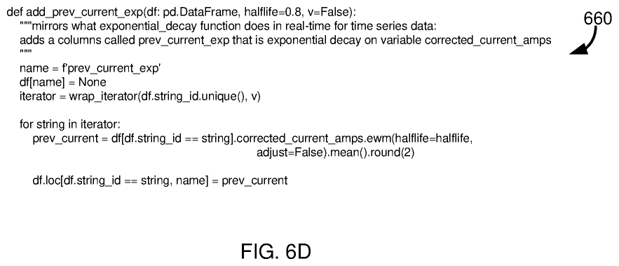

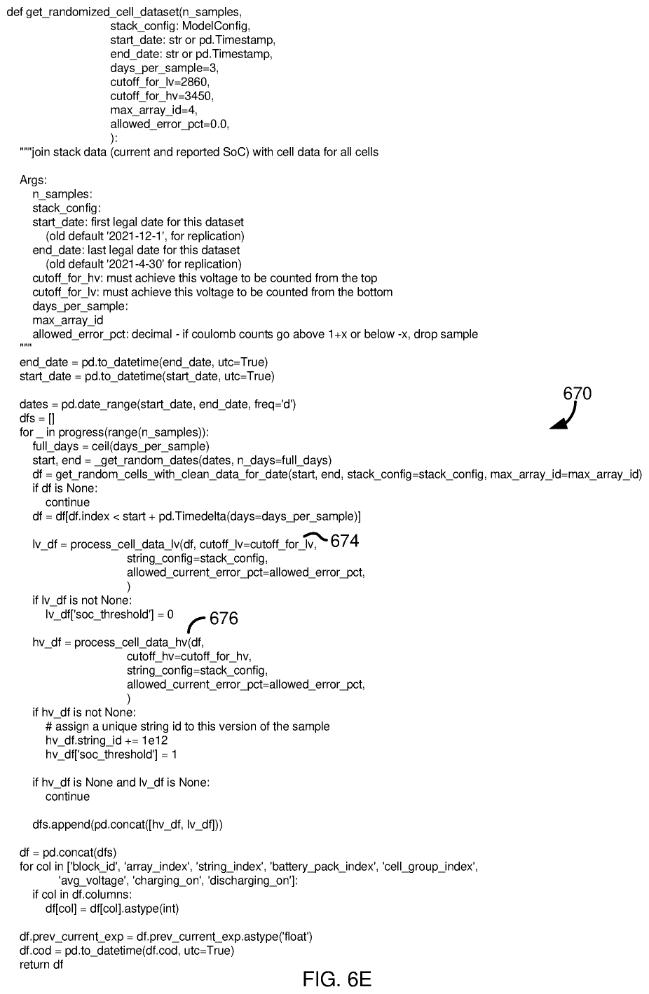

FIGS. 6A-6E provide example python code that can be used to process data for use in model creation. With reference first to FIG. 6A, when a current is calculated for data for particular battery cells, it can be desirable to account for a “balancer current” used during cell operation. A balancer current can be used to add or remove energy to or from one or more battery cells having a higher or lower state of charge than surrounding cells. In at least some cases, the balancer current can be measured separately from a discharge current representing energy being removed from a battery system (such as to provide energy external to a battery storage device, including to an electrical grid) and separately from a charge current originating outside the battery storage device (such as from an electrical grid or a renewable energy source).

In code 604 of FIG. 6A, a column is added to a data set that reflects a sum of a measured (“stack” or “rack”) current and a balancer current, where the balancer current can be measured as a charge current and a discharge current. In this case, the data set is referred to as a dataframe, which can represent multiple data points (sets of current, voltage, and temperature values) for multiple cells, such as over a particular time window. In the code 604, a balancer current is calculated as the sum of the product of the time the discharge current was on and the amps discharged and the product of the time the charge current was on and the amps charged. A corrected current is calculated as the sum of the measured current and the cell balancer current.

FIG. 6B illustrates example python code 630 that can be used to implement the high/low voltage checks described above. The code 630 analyzes voltage and error for a dataframe, and so the checks are performed for the dataframe as a collection (where, in some cases, a dataframe is not further processed if any of the constituent raw cell data does not satisfy voltage/error criteria). Respective data processing functions 632, 634 for processing data with respective the low and high voltage criteria, respectively, include respective coulomb counting functions 636, 638, where coulombs are counted from the bottom or top, respectively, of data in the data frames.

In FIG. 6C, functions 650, 652 provide code that implements the coulomb counting functionality called in the processing functions 636, 638. Referring first to function 650, the function counts coulombs for cells represented in the dataframe from top of the dataframe, where the coulomb count is for all cells in a dataframe multiplied by a time factor representing a sample length. For example, when a dataframe contains cell data over a one-minute time period, the time factor can be 1/60. A smallest coulomb count for a set of measurements for a given cell represented in the dataframe is determined. An allowed state of charge error value is calculated as the product of an estimated state of charge value and an allowed error percentage. If the maximum coulomb count for the battery cell is higher than the sum of the estimated state of charge and the allowed state of charge error value, or the minimum coulomb count is less than the allowed error, an error is raised. Otherwise, the coulomb count is saved for the respective cell.

The operation of the function 652 is similar to the operation of the function 650. The coulomb count is defined as the product of the corrected current amps, calculated as described above, and the time factor. A “boost” factor is calculated as the difference between the estimated state of charge for a respective cell in the dataframe and the maximum coulomb count for the cell over the relevant time period. The boost factor is then added to the coulomb count. The boost factor can be used to align state of charge values at the bottom.

An allowed error is calculated as described for the function 650. It is the determined whether the maximum coulomb count for the cell is greater than the estimated state of charge for the cell and the allowed error, or whether the minimum coulomb count is less than the allowed error. If so, an error is raised. Otherwise, the coulomb count is saved for the respective cell.

Returning again to the functions 636, 638 of FIG. 6B, after the coulombs are counted from the bottom or top, respectively, a previous cell current that is calculated based on an exponential decay function, which can use the function 660 shown in FIG. 6D.

FIG. 6E provides code 670 that can cause the creation and processing of dataframes as described above, and the combination of such dataframes to create a data set. The code 670 includes various configuration parameters, such as low voltage and high voltage cutoff values, a number of samples to be taken, a time period of data to be used in the sample, a number of days whose data should be included in a given sample, and an allowed error percentage. Lines 674, 676 of the code 670 call the functions 636, 638 of FIG. 6B. If such functions return without error, the values for a dataframe being processed are added to a dataset being constructed from the dataframes.

As discussed, a data set created using the above technique can be used to create various types of models that can be used to estimate a state of charge for a battery cell or a collection of battery cells. In some cases, a data set can be used as input for training a machine learning algorithm to provide a trained machine learning model.

Using a data set of this Example 5, the measured current, previous current, temperature, and voltage can be used as input, and the mean amp-hours can be used as labels to provide feedback to the machine learning algorithm. That is, for a neural network, model training will use input and labels to reduce an error or cost function by adjusting parameters (such as neuronal weights) of a machine learning model, where through training the error is reduced and desirably the training data is sufficient to product an acceptably low level of error for inference data. In some cases, part of a data set can be used for model training, and another part of the data set can be used to evaluate the performance of the machine learning model prior to putting the machine learning model to productive use.

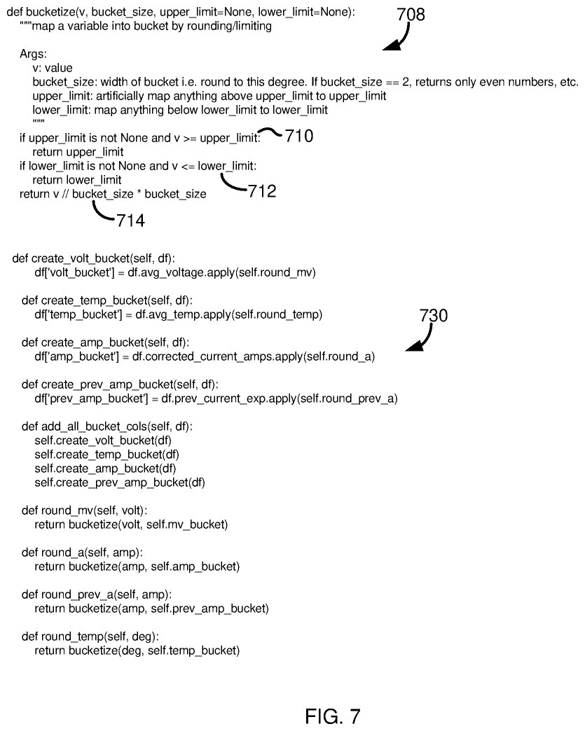

Alternatively, the data set can be used to provide a lookup table. For example, the data set can be divided into various “buckets” based on particular criteria, including as described with respect to the example code provided in FIG. 7.

FIG. 7 illustrates code 708 for a “bucketize” function. The bucketize function 708 includes parameters of a value, a bucket size, and optionally an upper limit or a lower limit. Bucket sizes (also referred to as “widths”) can be different (or can be the same) for different bucket types (such as voltage or temperature) and can be specified for a particular model, or for a particular model component. For example, while in some cases a model can be created using data for a large set of racks, such as racks in a single enclosure or in multiple enclosures, in other cases models can be defined for individual racks, or even individual battery cells. Creating models for collections of battery cell can be useful in a variety of scenarios, including when insufficient data is available to create accurate models for individual battery cells.

Code lines 710, 712 compare an input value to an upper limit or a lower limit defined for the input value, where the input value is assigned to a bucket defined for a respective limit if the input value satisfies criteria defined for the respective limit (such as meeting or exceeding the limit). Code line 714 is executed if the value is not assigned to an upper or lower limit bucket, and determines a bucket to which the value is assigned by using floor division for the value and the bucket size (that is, the result of dividing the input value by the bucket size, rounded down to the nearest whole number), multiplied by the bucket size. For example, if a bucket size of “2” was set, both values 24 and 25 would be assigned to a bucket for value 24. If a bucket size of “4” was set, then values 24, 25, 26, and 27 would all be assigned to the bucket for value 24.

Code 730 illustrates functions that call the bucketize function code 708 for assigning values to buckets for the different bucket types, where the respective functions include arguments providing the defined bucket size for a respective bucket type.

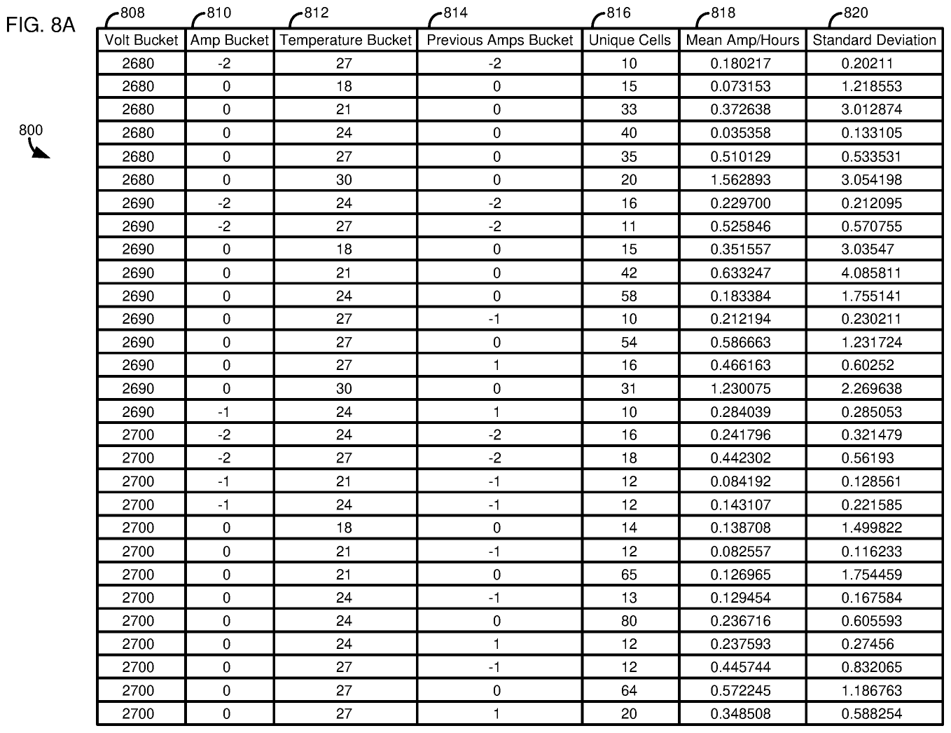

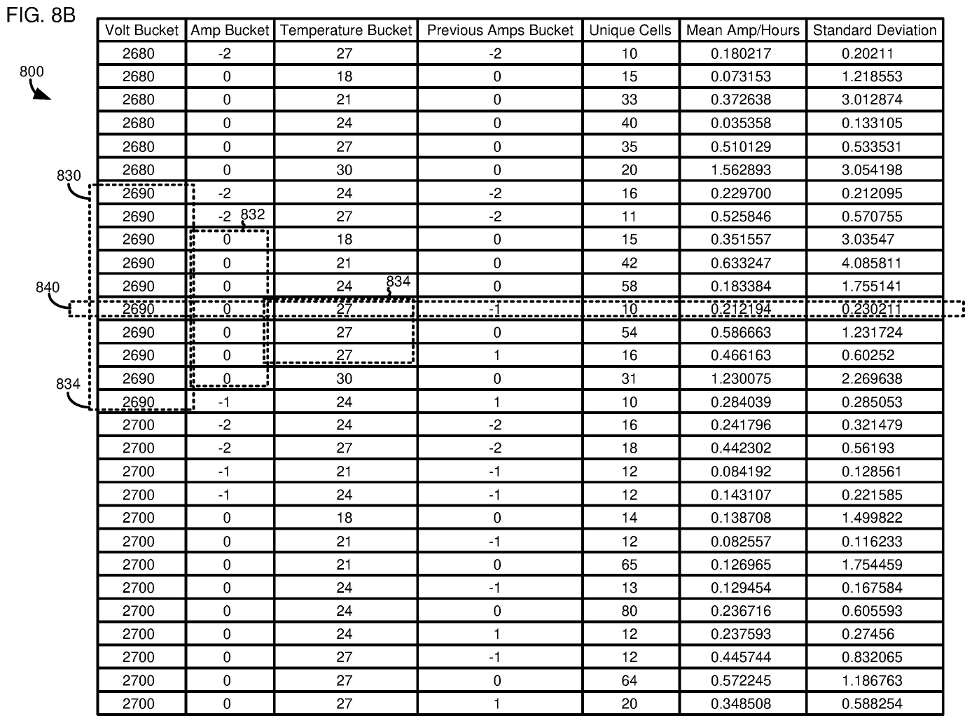

FIG. 8A illustrates an example lookup table 800 that can be produced using disclosed techniques. The lookup table 800 includes a plurality of columns corresponding to the various bucket types creating using a training data set, including a column 808 listing values for a voltage bucket, a column 810 listing values for an amperage bucket, a column 812 listing values for a temperature bucket, and a column 814 listing values for a bucket containing prior amperage readings. The table 800 further includes a column 816 the includes a number of unique cells having values falling into a given set of bucket values. That is, each row of the table represents a particular combination of bucket values into which values for individual data points in the data set fell (where a data point has a specific combination of values for voltage, amps, temperature, and prior amps), where the originally measured values can vary by the widths of the respective buckets.

Column 818 provides mean amp/hour (state of charge) values for battery cells having a combination of various bucket values. Column 820 provides a measure of error, such as the standard deviation, for amp/hour values of the column 818.

Generally, the process for using the lookup table 800 involves (1) obtaining a set of measured battery cell values to be used as input for the lookup table; (2) determining buckets into which the measured values fall (which can be equivalent to how values of the training data set are bucketized, as described in conjunction with FIG. 7); and (3) determining a row of the table 800 that matches the bucketized input values. For example, for a set of bucketized input vales for a measured/determined voltage, amps, temperature, and prior amperage values, it can be first be determined which rows of the column 808 correspond to the bucketed input voltage value.

From those rows, a subset of rows is determined that have both the bucketized voltage value and the corresponding bucketized amps value for the column 810. A further subset of that subset of rows is then determined that has the correct voltage bucket value, amp bucket value, and a corresponding bucketized temperature value for the column 812. A row corresponding to the bucketized input value is then determined from that subset of rows from the column 814 using the bucketized previous amps value. In response to a lookup request, the mean state of charge value in the column 818 can be returned, optionally in conjunction with the associated error value of the column 820.

FIG. 8B illustrates how the lookup table 800 can be used to obtain a state of charge estimate for a measured set of input values, such as a reading for a particular battery cell measured at a particular time. In particular, FIG. 8B illustrates the lookup table being used for a set of input values (2697, 0, 28, −1), where the columns 808-814 have respective bucket widths of (10, 1, 3, 1).

The bucketized value for (2697) is determined as (FLOOR(2697/10)*10), providing a value of 2690, which provides that the rows of a group 830 should be further analyzed to determine from which row the mean state of charge value should be provided. Looking at the amps bucket, the bucketized value for (0) is determined as (FLOOR(0/1)*1), providing a value of 0, which provides that the rows of a group 832 should be further analyzed. Turning to the temperature bucket, the bucketized value of (28) is determined as (FLOOR(28/3)*3), providing a value of 27. The partial set of bucketized values (2690, 0, 27) determines that the state of charge value from a row within a group 834 should be provided. The bucketized prior amps value of the input data set is determined as (FLOOR(−1/1)*1), providing a bucketized value of −1. A row 840 of the group 834 is the only row of the table 800 having the bucket values of (2690, 1, 27, −1), and so the state of charge value of 0.212194, optionally with the error value of 0.230211, is provided in response to the lookup table request.

In a particular implementation, the state of charge and error predictions can be used as input to the process 300 of FIG. 3 or the process 400 of FIG. 4.

### Example 6—Computing Systems

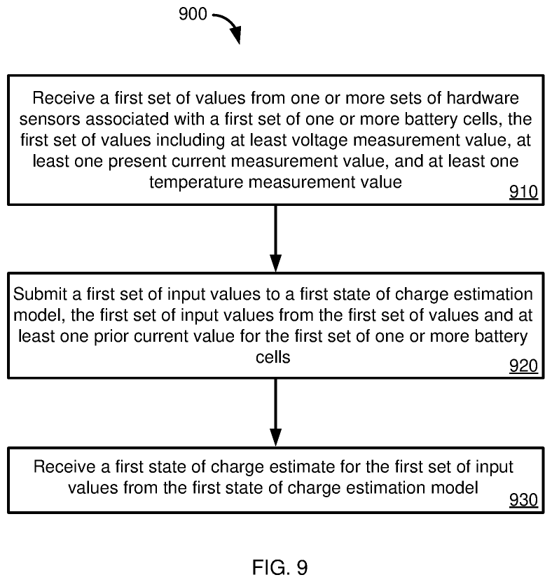

FIG. 9 is a flowchart of an example process 900 for obtaining a state of charge estimate for one or more battery cells. At 910, a first set of values is received from one or more sets of hardware sensors associated with a first set of one or more battery cells, the first set of values comprising at least voltage measurement value, at least one present current measurement value, and at least one temperature measurement value. A first set of input values is submitted at 920 to a first state of charge estimation model, the first set of input values from the first set of values and at least one prior current value for the first set of one or more battery cells. At 930, a first state of charge estimate is received for the first set of input values from the first state of charge estimation model.

### Example 7—Computing Systems

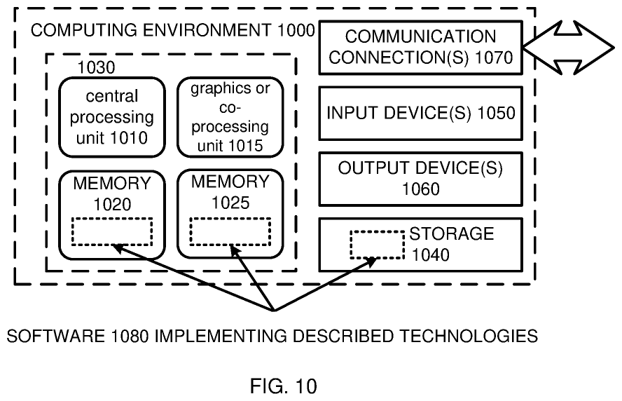

FIG. 10 depicts a generalized example of a suitable computing system 1000 in which the described innovations may be implemented. The computing system 1000 is not intended to suggest any limitation as to scope of use or functionality of the present disclosure, as the innovations may be implemented in diverse general-purpose or special-purpose computing systems.

With reference to FIG. 10, the computing system 1000 includes one or more processing units 1010, 1015 and memory 1020, 1025. In FIG. 10, this basic configuration 1030 is included within a dashed line. The processing units 1010, 1015 execute computer-executable instructions, such as for implementing techniques described in Examples 1-6. A processing unit can be a general-purpose central processing unit (CPU), processor in an application-specific integrated circuit (ASIC), or any other type of processor. In a multi-processing system, multiple processing units execute computer-executable instructions to increase processing power. For example, FIG. 10 shows a central processing unit 1010 as well as a graphics processing unit or co-processing unit 1015. The tangible memory 1020, 1025 may be volatile memory (e.g., registers, cache, RAM), non-volatile memory (e.g., ROM, EEPROM, flash memory, etc.), or some combination of the two, accessible by the processing unit(s) 1010, 1015. The memory 1020, 1025 stores software 1080 implementing one or more innovations described herein, in the form of computer-executable instructions suitable for execution by the processing unit(s) 1010, 1015.

A computing system 1000 may have additional features. For example, the computing system 1000 includes storage 1040, one or more input devices 1050, one or more output devices 1060, and one or more communication connections 1070. An interconnection mechanism (not shown) such as a bus, controller, or network interconnects the components of the computing system 1000. Typically, operating system software (not shown) provides an operating environment for other software executing in the computing system 1000, and coordinates activities of the components of the computing system 1000.

The tangible storage 1040 may be removable or non-removable, and includes magnetic disks, magnetic tapes or cassettes, CD-ROMs, DVDs, or any other medium which can be used to store information in a non-transitory way, and which can be accessed within the computing system 1000. The storage 1040 stores instructions for the software 1080 implementing one or more innovations described herein.

The input device(s) 1050 may be a touch input device such as a keyboard, mouse, pen, or trackball, a voice input device, a scanning device, or another device that provides input to the computing system 1000. The output device(s) 1060 may be a display, printer, speaker, CD-writer, or another device that provides output from the computing system 1000.

The communication connection(s) 1070 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

The innovations can be described in the general context of computer-executable instructions, such as those included in program modules, being executed in a computing system on a target real or virtual processor. Generally, program modules or components include routines, programs, libraries, objects, classes, components, data structures, etc. that perform particular tasks or implement particular abstract data types. The functionality of the program modules may be combined or split between program modules as desired in various embodiments. Computer-executable instructions for program modules may be executed within a local or distributed computing system.

The terms “system” and “device” are used interchangeably herein. Unless the context clearly indicates otherwise, neither term implies any limitation on a type of computing system or computing device. In general, a computing system or computing device can be local or distributed, and can include any combination of special-purpose hardware and/or general-purpose hardware with software implementing the functionality described herein.

In various examples described herein, a module (e.g., component or engine) can be “coded” to perform certain operations or provide certain functionality, indicating that computer-executable instructions for the module can be executed to perform such operations, cause such operations to be performed, or to otherwise provide such functionality. Although functionality described with respect to a software component, module, or engine can be carried out as a discrete software unit (e.g., program, function, class method), it need not be implemented as a discrete unit. That is, the functionality can be incorporated into a larger or more general-purpose program, such as one or more lines of code in a larger or general-purpose program.

For the sake of presentation, the detailed description uses terms like “determine” and “use” to describe computer operations in a computing system. These terms are high-level abstractions for operations performed by a computer, and should not be confused with acts performed by a human being. The actual computer operations corresponding to these terms vary depending on implementation.

### Example 8—Cloud Computing Environment

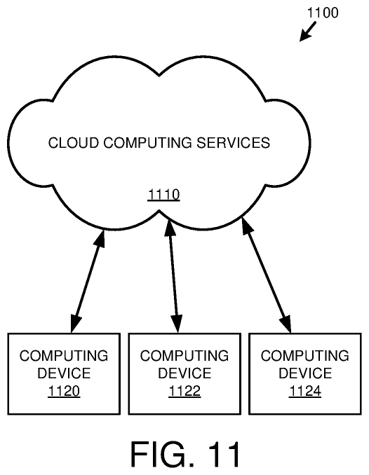

FIG. 11 depicts an example cloud computing environment 1100 in which the described technologies can be implemented. The cloud computing environment 1100 comprises cloud computing services 1110. The cloud computing services 1110 can comprise various types of cloud computing resources, such as computer servers, data storage repositories, networking resources, etc. The cloud computing services 1110 can be centrally located (e.g., provided by a data center of a business or organization) or distributed (e.g., provided by various computing resources located at different locations, such as different data centers and/or located in different cities or countries).

The cloud computing services 1110 are utilized by various types of computing devices (e.g., client computing devices), such as computing devices 1120, 1122, and 1124. For example, the computing devices (e.g., 1120, 1122, and 1124) can be computers (e.g., desktop or laptop computers), mobile devices (e.g., tablet computers or smart phones), or other types of computing devices. For example, the computing devices (e.g., 1120, 1122, and 1124) can utilize the cloud computing services 1110 to perform computing operators (e.g., data processing, data storage, and the like).

### Example 9—Implementations

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions or a computer program product stored on one or more computer-readable storage media, such as tangible, non-transitory computer-readable storage media, and executed on a computing device (e.g., any available computing device, including smart phones or other mobile devices that include computing hardware). Tangible computer-readable storage media are any available tangible media that can be accessed within a computing environment (e.g., one or more optical media discs such as DVD or CD, volatile memory components (such as DRAM or SRAM), or nonvolatile memory components (such as flash memory or hard drives)). By way of example, and with reference to FIG. 10, computer-readable storage media include memory 1020 and 1025, and storage 1040. The term computer-readable storage media does not include signals and carrier waves. In addition, the term computer-readable storage media does not include communication connections (e.g., 1070).

Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. It should be understood that the disclosed technology is not limited to any specific computer language or program. For instance, the disclosed technology can be implemented by software written in C, C++, C#, Java, Perl, JavaScript, Python, Ruby, ABAP, SQL, XCode, GO, Adobe Flash, or any other suitable programming language, or, in some examples, markup languages such as html or XML, or combinations of suitable programming languages and markup languages. Likewise, the disclosed technology is not limited to any particular computer or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

The disclosed methods, apparatus, and systems should not be construed as limiting in any way. Instead, the present disclosure is directed toward all novel and nonobvious features and aspects of the various disclosed embodiments, alone and in various combinations and sub combinations with one another. The disclosed methods, apparatus, and systems are not limited to any specific aspect or feature or combination thereof, nor do the disclosed embodiments require that any one or more specific advantages be present, or problems be solved.

The technologies from any example can be combined with the technologies described in any one or more of the other examples. In view of the many possible embodiments to which the principles of the disclosed technology may be applied, it should be recognized that the illustrated embodiments are examples of the disclosed technology and should not be taken as a limitation on the scope of the disclosed technology. Rather, the scope of the disclosed technology includes what is covered by the scope and spirit of the following claims.

What is claimed is:

1. A computing system comprising:
at least one memory;
one or more hardware processing units coupled to the at least one memory; and
one or more computer readable storage media storing computer-executable instructions that, when executed, cause the computing system to perform operations comprising:
receiving a first set of values from one or more sets of hardware sensors associated with a first set of one or more battery cells, the first set of values comprising at least voltage measurement value, at least one present current measurement value, and at least one temperature measurement value;
submitting a first set of input values to a first state of charge estimation model, the first set of input values from the first set of values and at least one prior current value for the first set of one or more battery cells; and
receiving a first state of charge estimate for the first set of input values from the first state of charge estimation model.

2. The computing system of claim 1, the operations further comprising:
subsequent to receiving the first state of charge estimate for the first set of input values, receiving a command to increase an amount of energy supplied to at least one battery cell of the first set of one or more battery cells; and
suppling energy to the at least one battery cell.

3. The computing system of claim 1, the operations further comprising:
subsequent to receiving the first state of charge estimate for the first set of input values, receiving a command to withdraw energy from at least one battery cell of the first set of one or more battery cells; and
withdrawing energy from the at least one battery cell.

4. The computing system of claim 1, the operations further comprising:
subsequent to receiving the first state of charge estimate for the set of input values, receiving a command to disconnect at least one battery cell of the first set of one or more battery cells from a circuit; and
disconnecting the at least one battery cell from the circuit.

5. The computing system of claim 1, wherein the first state of charge estimation model comprises a lookup table.

6. The computing system of claim 1, wherein the first state of charge estimation model comprises a machine learning model.

7. The computing system 1, the operations further comprising:
training the first state of charge estimation model, the training the first state of charge estimation model comprising:
receiving a plurality of training data sets, a given training data set of the plurality of training data sets comprising, for a second set of one or more battery cells, wherein the second set of one or more battery cells is the same as the first set of one or more battery cells or where one or more battery cells of the first set of one or more battery cells are not included in the second set of one or more battery cells, a second set of input values, the second set of input values comprising at least voltage measurement value, at least one current measurement value, at least one prior current measurement value, at least one temperature measurement value, and at least one state of charge estimate;
submitting at least a portion of the training data sets to a machine learning algorithm to provide a trained machine learning model.

8. The computing system of claim 7, the operations further comprising:
filtering the plurality of training data sets by comparing an error value associated with a given state of charge estimate with a first threshold and not submitting training data sets of the plurality of training data sets to the machine learning model that do not satisfy the first threshold.

9. The computing system of claim 8, wherein the filtering further comprises comparing the current measurement to one or more second thresholds and not submitting training data sets of the training data sets to the machine learning model that do not satisfy at least one threshold of the one or more second thresholds.

10. The computing system of claim 7, wherein the at least one state of charge estimate is produced by measuring coulombs provided to and withdrawn from battery cells of the second set of one or more battery cells.

11. The computing system of claim 1, the operations further comprising:
receiving a plurality of training data sets, a given training data set of the plurality of training data sets comprising, for a second set of one or more battery cells, wherein the second set of battery cells is the same as the first set of one or more battery cells or where one or more battery cells of the first set of one or more battery cells are not included in the second set of one or more battery cells, a second set of input values, the second set of input values comprising at least voltage measurement value, at least one current measurement value, at least one prior current measurement value, at least one temperature measurement value, and at least one state of charge estimate; and
generating a lookup table using at least a portion of the plurality of training data sets.

12. The computing system of claim 11, the operations further comprising:
filtering the plurality of training data sets by comparing an error value associated with a given state of charge estimate with a threshold and not using training data sets of the plurality of training sets that do not satisfy the threshold to generate the lookup table.

13. The computing system of claim 12, wherein the filtering further comprises comparing the current measurement value to one or more thresholds and not using training data sets of the plurality of training data sets that do not satisfy at least one threshold of the one or more thresholds to generate the lookup table.

14. The computing system of claim 1, the operations further comprising:
combining the first state of charge estimate with at least a second state of charge estimate.

15. The computing system of claim 14, wherein the combining the first state of charge estimate with the at least a second state of charge estimate is based at least in part on respective uncertainties associated with the first state of charge estimate and the at least a second state of charge estimate.

16. The computing system of claim 15, wherein the combining employs a Kalman filter.

17. The computing system of claim 13, wherein the at least a second state of charge estimate is based on a coulomb counting technique.

18. The computing system of claim 17, wherein the coulomb counting technique measure coulombs provided to, and coulombs withdrawn from, the first set of one or more battery cells.

19. A method, implemented in a computing system comprising at least one hardware processor and at least one memory coupled to the at least one hardware processor, the method comprising:
receiving a first set of values from one or more sets of hardware sensors associated with a first set of one or more battery cells, the first set of values comprising at least voltage measurement value, at least one present current measurement value, and at least one temperature measurement value;
submitting a first set of input values to a first state of charge estimation model, the first set of input values from the first set of values and at least one prior current value for the first set of one or more battery cells; and
receiving a first state of charge estimate for the first set of input values from the first state of charge estimation model.

20. One or more computer-readable storage media comprising:
computer-executable instructions that, when executed by a computing system comprising at least one hardware processor and at least one memory coupled to the at least one hardware processor, cause the computing system to receive a first set of values from one or more sets of hardware sensors associated with a first set of one or more battery cells, the first set of values comprising at least voltage measurement value, at least one present current measurement value, and at least one temperature measurement value;
computer-executable instructions that, when executed by the computing system, cause the computing system to submit a first set of input values to a first state of charge estimation model, the first set of input values from the first set of values and at least one prior current value for the first set of one or more battery cells; and
computer-executable instructions that, when executed by the computing system, cause the computing system to receive a first state of charge estimate for the first set of input values from the first state of charge estimation model.
